(19) United States
(12) Patent Application Publication
(10) Pub. No.: US 2024/0023279 A1
(43) Pub. Date: Jan. 18, 2024

(54) HEAT DISSIPATION MODULE AND ASSEMBLY METHOD THEREOF

(71) Applicant: FIVEGRAND INTERNATIONAL CO., LTD., New Taipei City (TW)

(72) Inventor: TING-JUI WANG, New Taipei City (TW)

(21) Appl. No.: 18/314,163

(22) Filed: May 9, 2023

(30) Foreign Application Priority Data
Jul. 18, 2022 (TW) 111126854

(51) Int. Cl. H05K 7/20

(52) U.S. Cl. CPC H05K 7/20318; H05K 7/2039

(57) ABSTRACT

A heat dissipation module and an assembly method thereof are introduced. The heat dissipation module includes a body, which is provided with a liquid cooler, and the heat dissipation module is disposed at a heat generator to perform heat dissipation. Thus, the heat dissipation module and the assembly method thereof provide a stable configuration and an efficiently improved heat dissipation effect.

### CROSS-REFERENCE TO RELATED APPLICATION

This non-provisional application claims priority under 35 U.S.C. § 119(a) on Patent Application No(s). 111126854 filed in Taiwan, R.O.C. on Jul. 18, 2022, the entire contents of which are hereby incorporated by reference.

### BACKGROUND OF THE INVENTION

### 1. Field of the Invention

The present disclosure relates to a heat dissipation module and an assembly method thereof, and in particular to a heat dissipation module providing a stable configuration and an efficiently improved heat dissipation effect, and an assembly method thereof.

### 2. Description of the Related Art

Heat is usually generated during the operation of an electronic apparatus, and thus a gas-heat dissipation or liquid-heat dissipation apparatus needs to be provided to meet heat dissipation requirements.

However, limited by an internal space of an electronic apparatus, it is a frequent occurrence that a gas or a liquid may not be effectively guided for heat dissipation, resulting in degraded heat dissipation efficiency.

### BRIEF SUMMARY OF THE INVENTION

On the basis of at least one embodiment of the present disclosure, a heat dissipation module and an assembly method thereof of the present disclosure provide a stable configuration and an efficiently improved heat dissipation effect.

To achieve the above and other objects, the present disclosure provides a heat dissipation module and an assembly method thereof. The heat dissipation module includes a body, which is provided therein with a liquid cooler or a gaseous cooler, and the heat dissipation module is disposed at a heat generator to perform heat dissipation.

The present disclosure further provides an assembly method of a heat dissipation module to dispose, assemble, couple, weld, or bond a body of the heat dissipation module by an automated process to an object or a heat generator, such that the body or the heat dissipation module is disposed, assembled, coupled, welded, or bonded at the object or the heat generator.

In an embodiment of the present invention, a liquid cooler receives a heat source of the heat generator and becomes a gas, and is condensed into a liquid in the body to perform heat dissipation.

In an embodiment of the present invention, the body is provided with a condenser, which is used to condense a gas into a liquid.

In an embodiment of the present invention, the condenser is a condenser pipe, a metal body, a heat sink, a cooling fluid, a cooling gas, or a cooling fin.

In an embodiment of the present invention, the condenser is provided with a flow channel for a liquid fluid or a gaseous fluid to flow.

In an embodiment of the present invention, the condenser is provided with a fan, which is used for heat dissipation.

In embodiments of the present invention, the body is provided with a heat sink used to guide, absorb, or dissipate a heat source between the heat generator and the liquid cooler or the gaseous cooler, or the heat sink is connected to a gas-cooling device to perform heat dissipation, or the heat sink is connected to a liquid-cooling device to perform heat dissipation.

In an embodiment of the present invention, an intermediate heat sink or a heat sink medium is provided between the body and the heat generator, wherein the intermediate heat sink or the heat sink medium is used to guide or absorb a heat source between the body and the heat generator.

In an embodiment of the present invention, the body is provided with a fan, which is used for heat dissipation.

In an embodiment of the present invention, the body is provided with an assembly element, which assembles the body at the object.

In an embodiment of the present invention, the assembly element has an elastic force to press and arrange the assembly element at the body.

In an embodiment of the present invention, the heat generator is disposed at the object, and the object is a printed circuit board or an object having a circuit.

In embodiments of the present invention, the heat generator is an integrated circuit (IC), a central processing unit (CPU), a graphics processing unit (GPU), an object that generates heat after energization, or a heat generating object.

In embodiments of the present invention, the liquid cooler is a water cooler, an oil cooler, water, a liquid object, or an engineering liquid.

In an embodiment of the present invention, the body is provided therein with a non-liquid space, which is used to accommodate a gas formed from a liquid.

In embodiments of the present invention, the body is provided therein with a non-liquid space, and the non-liquid space is located between the liquid cooler and the condenser, or the non-liquid space is located in the liquid cooler, or the non-liquid space is located in the condenser.

In embodiments of the present invention, the body, the heat sink, or the condenser is provided with an information transmission assembly or a light emitter, and the information transmission assembly or the light emitter is used to transmit or display a temperature of the body, the heat dissipation module, the liquid cooler, or the gaseous cooler, or detect or display a temperature of the non-liquid space, or detect or display a temperature of the condenser, or detect or display a temperature of the heat sink, or detect or display heat dissipation information, temperature information, or light emitting display of the heat generator, the liquid cooler, or the condenser.

In embodiments of the present invention, the body, the heat dissipation module, or the condenser is provided with a light emitter, which is used to display heat dissipation information or temperature information of the body, the heat dissipation module, or the condenser.

In an embodiment of the present invention, the body is provided with a filler, which is used to fill the liquid condenser.

In an embodiment of the present invention, the filler includes a switch.

In an embodiment of the present invention, a liquid displacement device is further included. The liquid displacement device moves the liquid cooler to the heat sink or the condenser to perform heat dissipation.

In an embodiment of the present invention, the body is provided with one or more heat sinks, and at least one of the heat sinks is provided with a flow channel used to guide flow of the liquid cooler.

In an embodiment of the present invention, the body is provided with a heat sink, which is connected to the gas-cooling device to perform heat dissipation.

In embodiments of the present invention, the gas-cooling device imports compressed air, such that one end of the gas-cooling device imports cold air into the heat sink, a heat conductor, a cooler, or the body to perform heat dissipation, heat conduction, or cooling, and one other end of the gas-cooling device exports hot air.

In an embodiment of the present invention, the gas-cooling device is a vortex tube, such that one end of the gas-cooling device imports air and one other end of the gas-cooling device exports hot air.

In an embodiment of the present invention, the body is provided with a heat sink, and the heat sink is provided with a flow channel used to import cold air to perform heat dissipation of the heat generator.

In embodiments of the present invention, the body, the heat sink, or the condenser is provided with a temperature detecting element, which is used to detect a temperature of the liquid cooler, or detect a temperature of the non-liquid space, or detect a temperature of the condenser, or detect a temperature of the heat sink, or detect a temperature of the heat generator.

In an embodiment of the present invention, the body or the heat dissipation module is picked up by a tool or an automated process, and is compared with a configuration position of the object or the heat generator by a comparison device to perform disposing, assembling, coupling, welding, or a bonding.

In an embodiment of the present invention, the body or the heat dissipation module is picked up by a tool or an automated process to move the body or the heat dissipation module to a predetermined height distanced from the object or the heat generator, and the body or the heat dissipation module is released or loosened, such that the body or the heat dissipation module is disposed, assembled, coupled, welded, or bonded at the object or the heat generator.

In an embodiment of the present invention, the body or the heat dissipation module is picked up by a tool or an automated process to move the body or the heat dissipation module, the body or the heat dissipation module is elastically pressed downward by the tool, and the body or the heat dissipation module is released or loosened, such that the body or the heat dissipation module is disposed, coupled, welded, or bonded at the object or the heat generator.

In an embodiment of the present invention, the body or the heat dissipation module is picked up by a tool or an automated process to move the body or the heat dissipation module, the tool senses that the body or the heat dissipation module comes into contact with the object or the heat generator, and the body or the heat dissipation module is released or loosened, such that the body or the heat dissipation module is disposed, assembled, coupled, welded, or bonded at the object or the heat generator.

In an embodiment of the present invention, the body or the heat dissipation module is picked up by a tool or an automated process to move the body or the heat dissipation module to the object or the heat generator, the body or the heat dissipation module is pressed downward by the tool, and the body or the heat dissipation module is released or loosened, such that the body or the heat dissipation module is disposed, assembled, coupled, welded, or bonded at the object or the heat generator.

In an embodiment of the present invention, the tool is a vacuum device, a fastener, a magnetic device, or an elastic device.

In embodiments of the present invention, the body and the object or the heat generator are assembled or coupled by means of heat welding, coating, assembling, bonding, fastening, fixing with a fixed element, sealing or packaging, or the object is a PCB, an iron plate, a metal body, or a plastic body.

In an embodiment of the present invention, the liquid cooler is added into the body after the body is disposed, placed, assembled, or coupled at the object or the heat generator, or the liquid cooler is added before the body is disposed at the object or the heat generator.

In an embodiment of the present invention, the body is first welded, assembled or coupled at the heat generator or the object, and is then fixed, sealed, or packaged by a fixing element.

In an embodiment of the present invention, the body is first welded, assembled, or coupled at the heat generator or the object and fixed, sealed, or packaged a fixing element, and the liquid cooler is added into the body.

In an embodiment of the present invention, the fixing element is a viscous element, a jelly element, a welding element, a plastic body, solder, glue, a thermoplastic element, or a heat curable element.

In an embodiment of the present invention, the body or the heat dissipation module is picked up by a tool or an automated process to move the body or the heat dissipation module to the object or the heat generator, and the body or the heat dissipation module is released or loosened, such that the body or the heat dissipation module is disposed, assembled, coupled, welded, or bonded at the object or the heat generator.

In an embodiment of the present invention, the body has a limiting portion or an anti-rotation portion used to limit or prevent rotation of a corresponding structure of the object, wherein the object is a PCB, an iron plate, a metal body, or a plastic body.

In an embodiment of the present invention, the heat dissipation module or the body is welded or bonded at the object or the heat generator to dispose the heat dissipation module or the body at the heat generator or the object.

In an embodiment of the present invention, a descending, sinking, or downward force or traction is produced by heat welding performed for cooling the solder from a liquid state to a solid state, or a descending, sinking, or downward force or traction is produced by bonding, such that the heat dissipation module or the body adheres to, leans against, or becomes close to the heat generator or the object.

### BRIEF DESCRIPTION OF THE DRAWINGS

To more clearly describe the technical solutions of the embodiments of the present disclosure and the prior art, accompanying drawings that need to be used as required in the embodiments are to be briefly introduced. It is obvious that the accompanying drawings below are merely some embodiments of the present disclosure, and other accompanying drawings can be obtained on the basis of the accompanying drawings by a person of ordinary skill in the art without involving any inventive skill.

FIG. 1 is a first schematic diagram of a state of use according to an embodiment of the present disclosure.

FIG. 2 is a second schematic diagram of a state of use according to an embodiment of the present disclosure.

FIG. 3 is a schematic diagram of a state of use according to an embodiment of the present disclosure.

FIG. 4 is a schematic diagram of a state of use according to an embodiment of the present disclosure.

FIG. 5 is a schematic diagram of a state of use according to an embodiment of the present disclosure.

FIG. 6 is a schematic diagram of a state of use according to an embodiment of the present disclosure.

FIG. 7 is a schematic diagram of a state of use according to an embodiment of the present disclosure.

FIG. 8 is a schematic diagram of a state of use according to an embodiment of the present disclosure.

FIG. 9 is a schematic diagram of a state of use according to an embodiment of the present disclosure.

FIG. 10 is a schematic diagram of a state of use according to an embodiment of the present disclosure.

FIG. 11 is a schematic diagram of a state of use according to an embodiment of the present disclosure.

FIG. 12 is a schematic diagram of a state of assembly according to an embodiment of the present disclosure.

FIG. 13 is a schematic diagram of a state of assembly according to an embodiment of the present disclosure.

FIG. 14 is a schematic diagram of a state of assembly according to an embodiment of the present disclosure.

FIG. 15 is a schematic diagram of a state of assembly according to an embodiment of the present disclosure.

FIG. 16 is a schematic diagram of a state of assembly according to an embodiment of the present disclosure.

FIG. 17 is a schematic diagram of a state of assembly according to an embodiment of the present disclosure.

FIG. 18 is a schematic diagram of a state of assembly according to an embodiment of the present disclosure.

### DETAILED DESCRIPTION OF THE INVENTION

A heat dissipation module and an assembly method thereof according to embodiments of the present disclosure are further described with the accompanying drawings below.

The above and other technical details, features and effects of the disclosure are to become more readily apparent with the detailed description of the preferred embodiments given with reference to the drawings below. It should be noted that, the directional terms used in the embodiments below, for example, upper, lower, left, right, front, and back are given merely with reference to the directions of the accompanying drawings. Thus, the directional terms are for illustration purposes and are not to be construed as limitations to the present disclosure. Moreover, in the embodiments below, the same or similar elements are represented by the same or similar denotations or numerals.

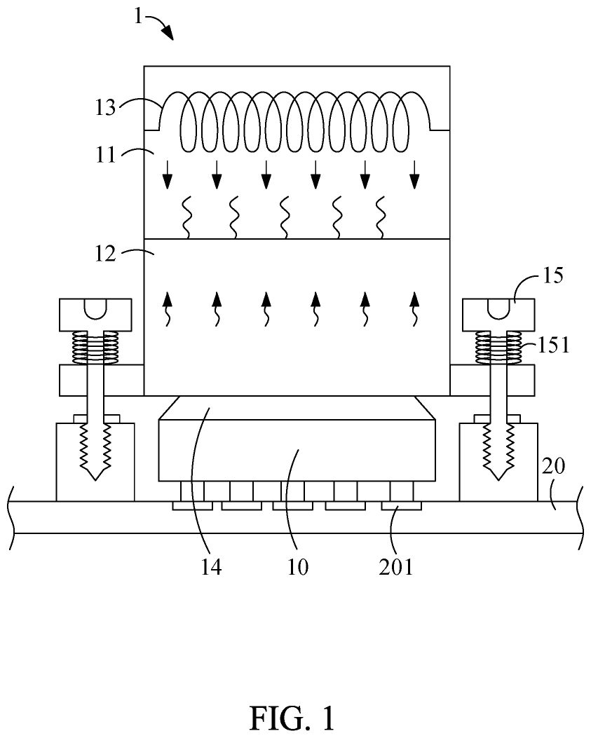

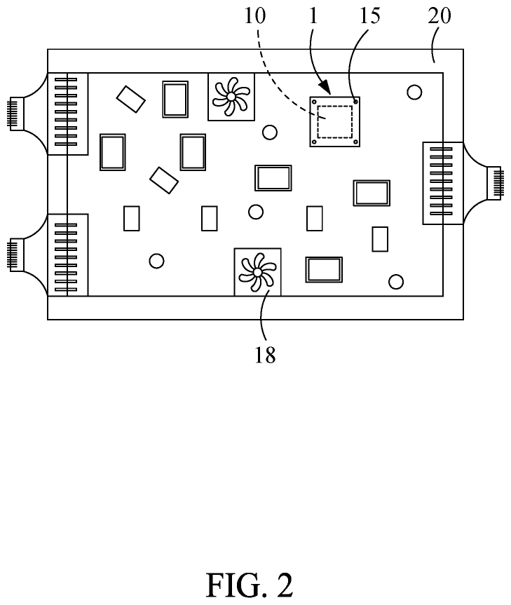

Refer to FIG. 1 and FIG. 2 showing a heat dissipation module and an assembly method of the present disclosure. The heat dissipation module 1 includes a body 11, which is provided therein with a liquid cooler 12 (or a gaseous cooler), and the heat dissipation module 1 may have the body 11 disposed at a heat generator 10 to perform heat dissipation.

For assembly and use, a welding portion 201 may be used to assemble the heat generator 10 at an object 20 by means of the surface mount technology (SMT) or an automated process, and the body 11 is disposed at the heat generator 10 or the object 20, such that the body 11, the heat generator 10 and the object 20 achieve an effect of a stable configuration. Moreover, heat dissipation of the heat generator 10 is performed by the liquid cooler 12 in the body 10, hence achieving the effect of efficient heat dissipation.

In one embodiment of the present disclosure, the body 11 (or the heat dissipation module 1) is welded or bonded at the object 20, and a descending, sinking, or downward force or traction is produced by heat soldering or heat welding performed for cooling the solder or welding material from a liquid state to a solid state, or a descending, sinking, or downward force or traction is produced by bonding, such that the heat dissipation module 1 or the body 11 adheres to, leans against, or becomes close to the heat generator 10 or the object 20.

In an embodiment of the present disclosure, solder paste, solder balls, or an adhesive become a liquid state or a soft body due to heating during the soldering or welding process, and then cools to again become a solid liquid or a hard body, wherein the solder paste, solder balls, or adhesive may be disposed at the body 11, the heat dissipation module 1, the object 20, or the heat generator 10, thereby enabling the present disclosure to better meet actual assembly or heat dissipation requirements.

In an embodiment of the present disclosure, the liquid cooler 12 receives a heat source of the heat generator 10 and becomes a gas, and the liquid cooler 12 is condensed to a liquid in the body 11 to perform heat dissipation, hence achieving the effect of efficient heat dissipation.

In an embodiment of the present disclosure, the body 11 is provided with a condenser 13, which is used to condense a gas into a liquid. Thus, the liquid condenser 12 receives the heat source of the heat generator 10 and becomes a gas, and the condenser 13 is condensed into a liquid in the body 11, hence achieving the effect of efficient heat dissipation.

In an embodiment of the present disclosure, the condenser 13 is a condenser pipe, a metal body, a heat sink, a cooling fluid, a cooling gas, or a cooling fin, thereby enabling the present disclosure to better meet actual heat dissipation requirements.

In an embodiment of the present disclosure, an intermediate heat sink 14 (or a heat sink medium) is provided between the body 11 and the heat generator 10, wherein the intermediate heat sink 14 is used to guide, absorb, or dissipate the heat source between the body 11 and the heat generator 10, thereby enabling the present disclosure to better meet actual heat dissipation requirements.

In an embodiment of the present disclosure, the body 11 is provided with an assembly element 15, which assembles the body 11 at the object 20. The assembly element 15 coordinates with an elastic component 151 and thus has an elastic force, such that the assembly element 15 can be stably pressed and arranged at the body 11, thereby enabling the present disclosure to better meet actual assembly requirements.

In an embodiment of the present disclosure, the object 20 may be a printed circuit board (PCB) or an object having a circuit, the heat generator 10 may be an integrated circuit (IC), a central processing unit (CPU), a graphics processing unit (GPU), an object that generates heat after energization, or a heat generating body, and the liquid cooler 12 may be a water cooler, an oil cooler, water, a liquid object, or an engineering liquid, thereby enabling the present disclosure to better meet actual heat dissipation requirements.

In an embodiment of the present disclosure, the body 11 is provided therein with a non-liquid space 16, which is used to accommodate a gas formed from the liquid cooler 12 that is a liquid.

In an embodiment of the present disclosure, the non-liquid space 16 is located between the liquid cooler 12 and the condenser 13 (or the non-liquid space 16 is located in the liquid cooler 12, or the non-liquid space 16 is located in the condenser 13), such that the non-liquid space 16 accommodates a gas formed from the liquid cooler 12 that is a liquid.

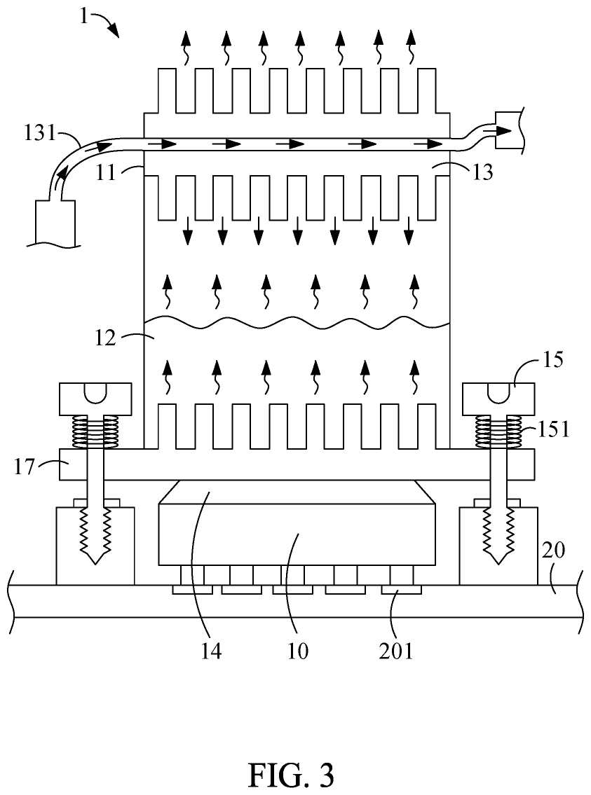

As shown in FIG. 3, in an embodiment of the present disclosure, a difference from the above embodiments is that, the condenser 13 has a flow channel 131 which is for a liquid fluid or a gaseous fluid to flow, and the body 11 is provided with a heat sink 17 (or a cooler, shown in the drawing). The flow channel 131 is provided at the heat sink 17 (or cooler), and is used to import cold air or a gas to perform heat dissipation or cooling of the heat generator 10 (or the liquid cooler 12), wherein the heat sink 17 is used to guide, absorb, or dissipate a heat source between the heat generator 10 and the liquid cooler 12. As such, heat dissipation of the heat generator is performed by using the liquid cooler 12 in the body 11, and heat dissipation is further performed with the coordination of the liquid fluid or the gaseous fluid in the flow channel of the condenser 13 as well as the heat sink 17 at the same time, hence achieving the effect of efficient heat dissipation.

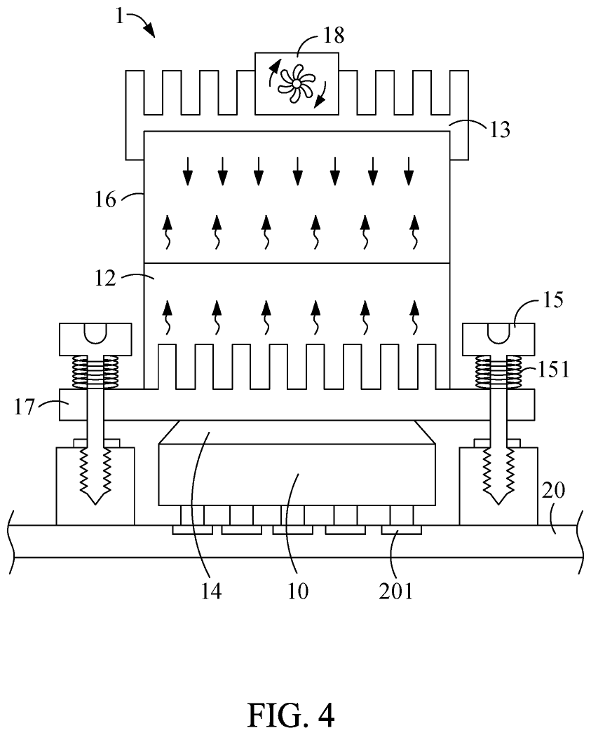

Referring to FIG. 4, in an embodiment of the present disclosure, a difference from the above embodiments is that, the condenser 13 (or the body 11) is provided with a fan 18, which is used to perform heat dissipation of the condenser 13, such that the condenser 13 coordinates with the fan 18 to condense a gas into a liquid. Thus, the liquid condenser 12 receives the heat source of the heat generator 10 and becomes a gas, and the condenser 13 is condensed into a liquid in the body 11 to perform heat dissipation, hence achieving the effect of efficient heat dissipation.

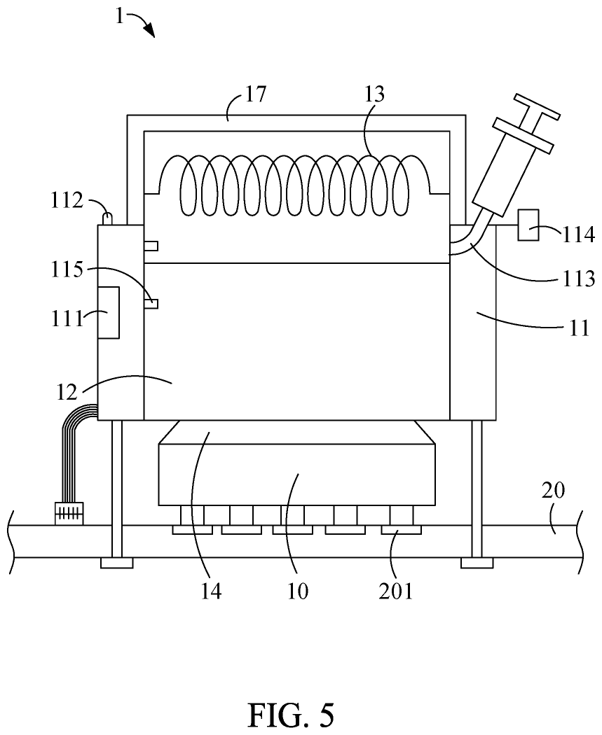

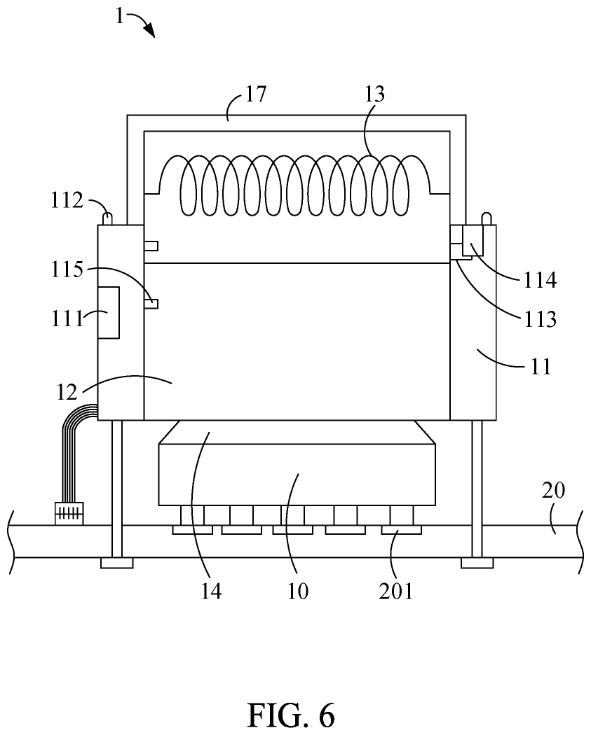

Referring to FIG. 5 and FIG. 6, in an embodiment of the present disclosure, a difference from the above embodiments is that, the body 11 is provided with an information transmission assembly 111, which is used to transmit heat dissipation information or temperature information of the body 11 (the heat dissipation module 1, the liquid cooler 12, or the condenser); the body 11 (the heat dissipation module 1 or the condenser 13) is provided with a light emitter 112, which is used to display heat dissipation information or temperature information of the body 11, the heat dissipation module 1, or the condenser 13; the body 11 is provided with a filler 113, which is used to fill the liquid cooler 12, wherein the filler 113 includes a switch 114, thereby enabling the present disclosure to better meet actual heat dissipation requirements.

In an embodiment of the present disclosure, the body 11 (the heat sink 17 or the condenser 13) is provided with a temperature detecting element 115, which is used to detect a temperature of the liquid cooler 12, or detect a temperature of the non-liquid space 16 or a temperature of the condenser 13 or the heat sink 17, or detect a temperature of the heat generator 10, thereby enabling the present disclosure to better meet actual heat dissipation requirements.

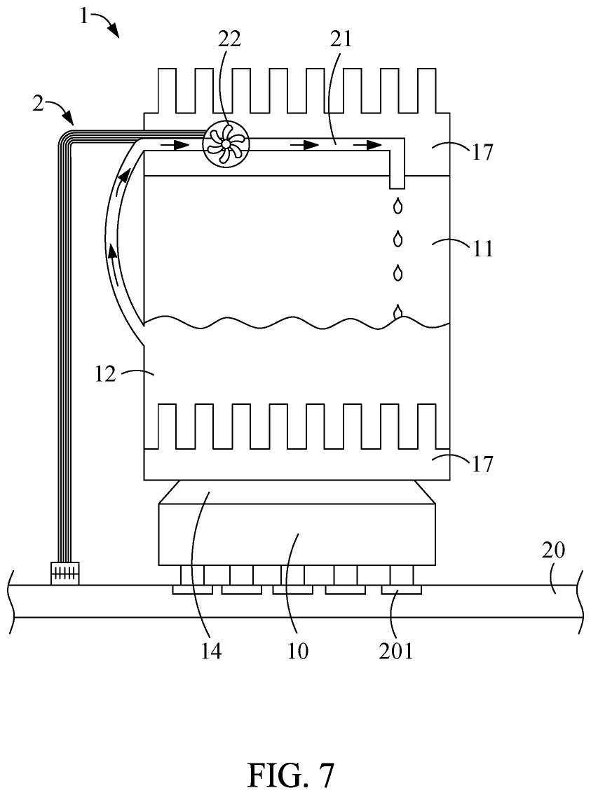

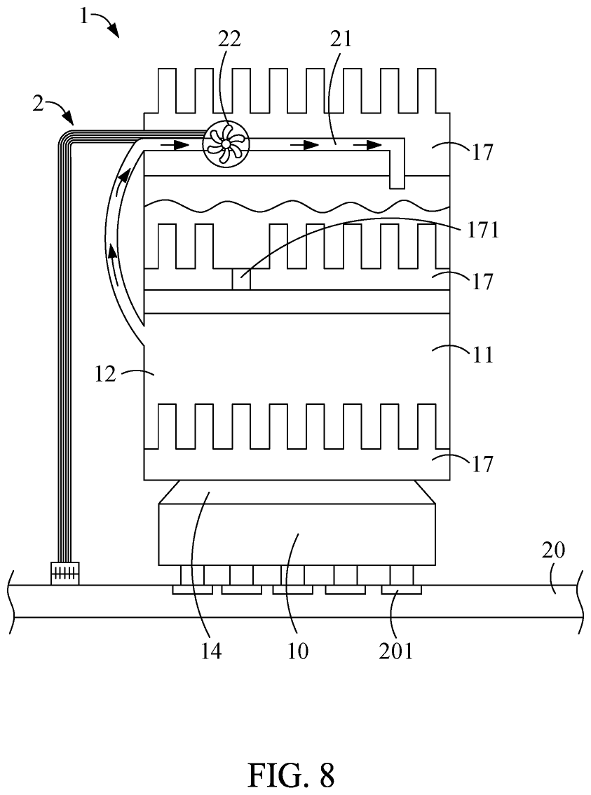

Referring to FIG. 7 and FIG. 8, in an embodiment of the present disclosure, a difference from the above embodiments is that, a liquid displacement device 2 is further included. The liquid displacement device 2 is provided with a flow channel 21 and a pump 22, and moves the liquid condenser 12 by using the coordination of the flow channel 21 and the pump 22 to the heat sink 17 (or the condenser 13) to perform heat dissipation.

In an embodiment of the present disclosure, the body 11 is provided with one or more heat sinks 17, and at least one of the heat sinks 17 is provided with a flow channel 171 used to guide the liquid condenser 12, such that the liquid displacement device 2 moves the liquid condenser 12 through the flow channel 171 to the heat sink 17 to perform heat dissipation, thereby enabling the present disclosure to better meet actual heat dissipation requirements.

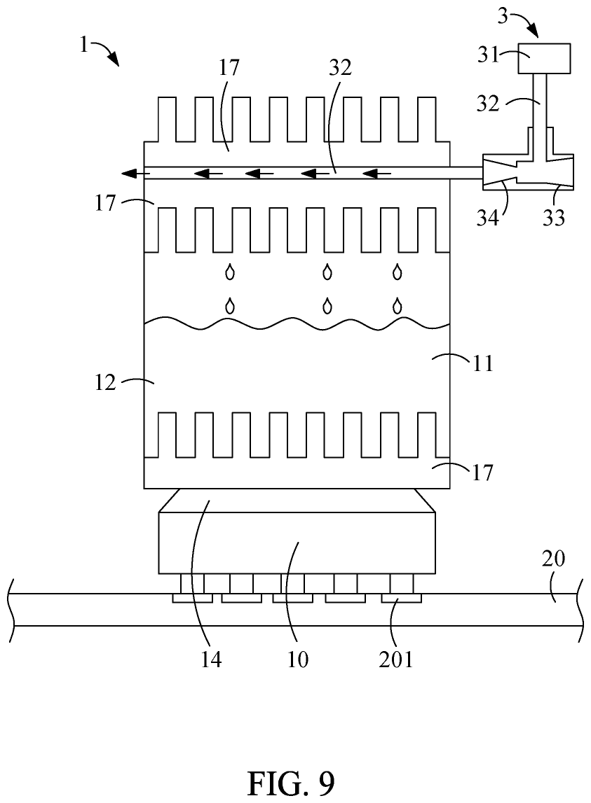

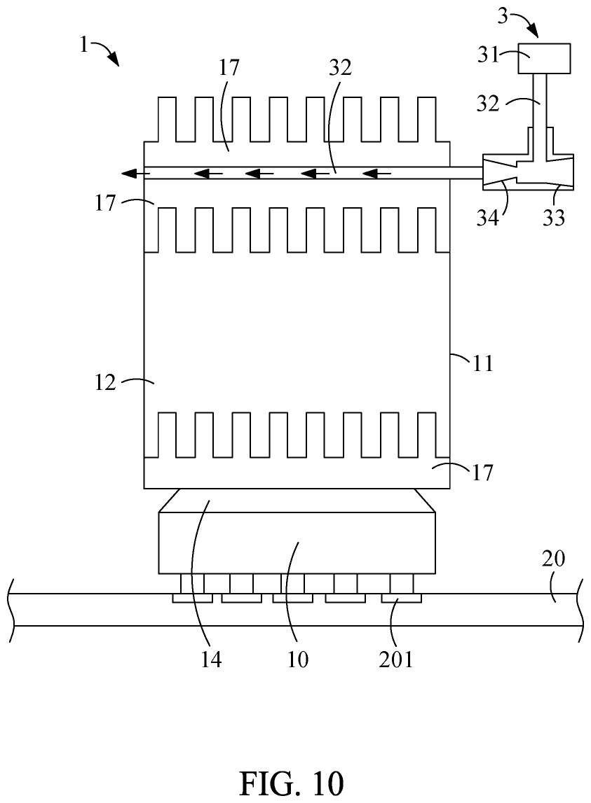

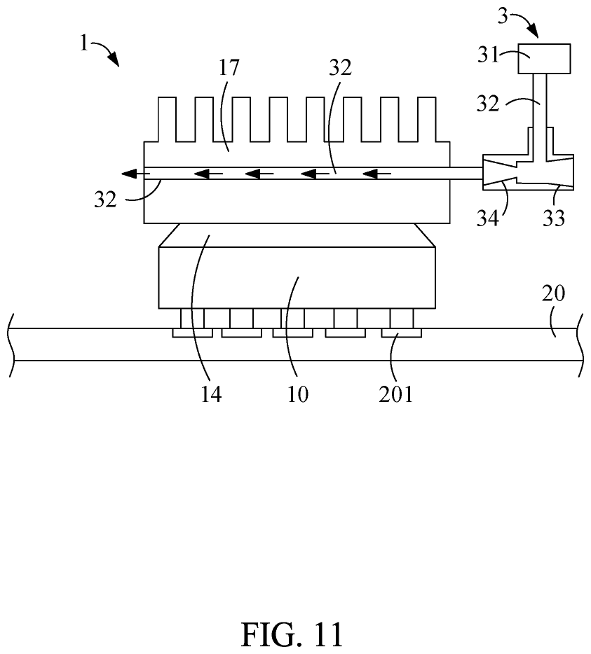

Referring to FIG. 9 to FIG. 11, in an embodiment of the present disclosure, a difference from the above embodiments is that, the heat sink 17 is connected to a gas-cooling device 3 to perform heat dissipation.

In an embodiment of the present disclosure, the gas-cooling device 3 includes an air compressor 31, flow channels 32 and 33, and a vortex tube 34. The air compressor 3 of the gas-cooling device 3 imports compressed air, such that the flow channel 32 on one end of the gas-cooling device 3 coordinates with the vortex tube 34 to import cold air into the heat sink 17 (a heat conductor, a cooler, or the body 11, not shown) to perform heat dissipation, heat conduction, or cooling, and the flow channel 33 on the other end of the gas-cooling device 3 exports hot air, thereby enabling the present disclosure to better meet actual heat dissipation requirements.

In an embodiment of the present disclosure, the gas-cooling device 3 may be a vortex tube, such that one end of the gas-cooling device 3 imports cold air and the other end exports hot air. In addition, the heat sink 17 is disposed at the body 11, and the heat sink 17 is provided with a flow channel 32 which is used to import cold air to perform heat dissipation of the heat generator 10, thereby enabling the present disclosure to better meet actual heat dissipation requirements.

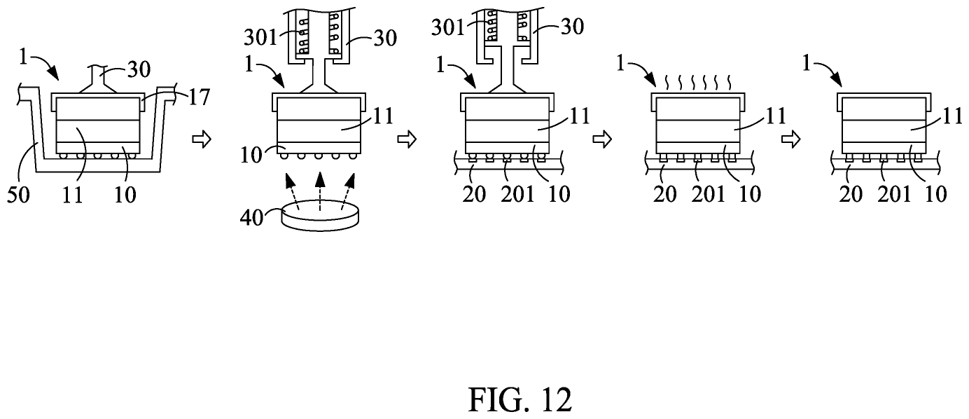

Referring to FIG. 12, in an embodiment of the present disclosure, a difference from the above embodiments is that, during the assembly of the heat dissipation module 1, the body 11 (or including the heat dissipation module 1 of the heat generator 10) is picked up by a tool 30, and is compared with a configuration position of the object 22 by a comparison device 40 so as to perform disposing, assembling, welding, soldering, or bonding.

In an embodiment of the present disclosure, the body 11 (or the heat dissipation module 1) is moved by the tool 30 to the object 20 (or the heat generator 10), and the body 11 (or the heat dissipation module 1) is released or loosened by the tool 30, such that the body 11 (or the heat dissipation module 1) is disposed, assembled, coupled, welded, soldered, or bonded at the body 20 (or the heat generator 10).

In an embodiment of the present disclosure, the body 11 (or the heat dissipation module 1 including the heat generator 10) in a carrier 50 is picked up by the tool 30 and moved by the tool 30 to a default height distanced from an assembly position of the object 20 or the heat generator 10, and the body 11 (or the heat dissipation module) is released or loosened by the tool 30 so as to perform assembly as being disposed, coupled, welded, soldered, or bonded at the assembly position of the object 20; or the body 11 (or the heat dissipation module 1 including the heat generator 10) is elastically pressed downward with the coordination of an elastic device 301 and sensed by the tool 30, the body 11 is released or loosened by the tool 30, and the assembly element 15 is disposed, assembled, coupled, welded, soldered, or bonded at the assembly position of the object 20 to perform assembly, coupling, welding, soldering, or bonding, such that the body 11 is disposed, assembled, coupled, welded, soldered, or bonded at the assembly position of the object 20, thereby enabling the present disclosure to better meet actual assembly requirements.

In an embodiment of the present disclosure, the tool 30 is a vacuum device, a fastener, a magnetic device, or an elastic device, thereby enabling the present disclosure to better meet actual assembly requirements.

In an embodiment of the present disclosure, the body 11 and the object 20 or the heat generator 10 are assembled or coupled by means of heat welding, soldering, coating, assembling, bonding, fastening, and fixing, sealing, or packaging with a fixed element 19, or the object 20 may be a PCB, an iron plate, a metal body, or a plastic body, thereby enabling the present disclosure to better meet actual assembly requirements. In this embodiment, the body 11 and the object 20 or the heat generator 10 are welded or soldered and combined by using the welding portion 201.

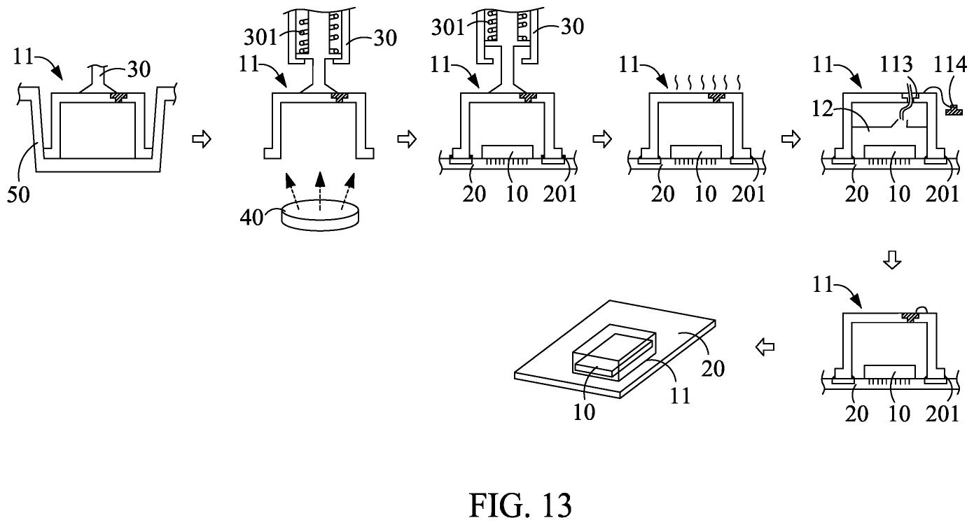

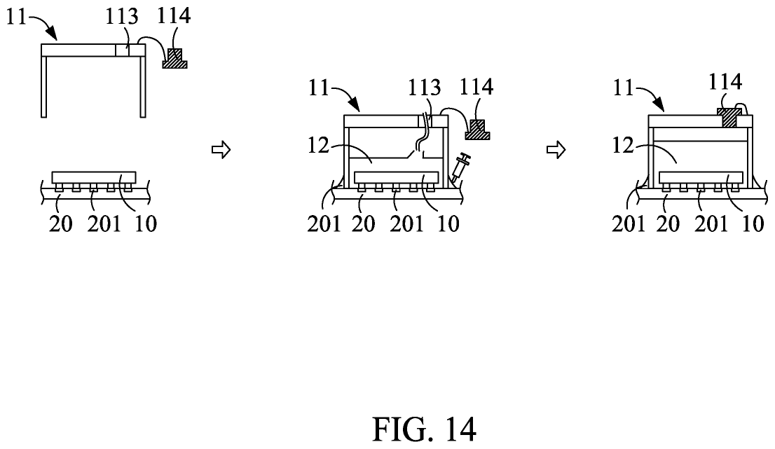

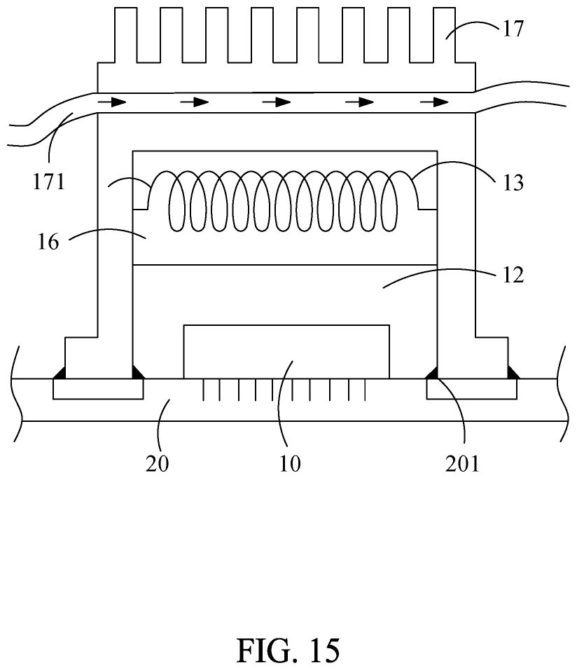

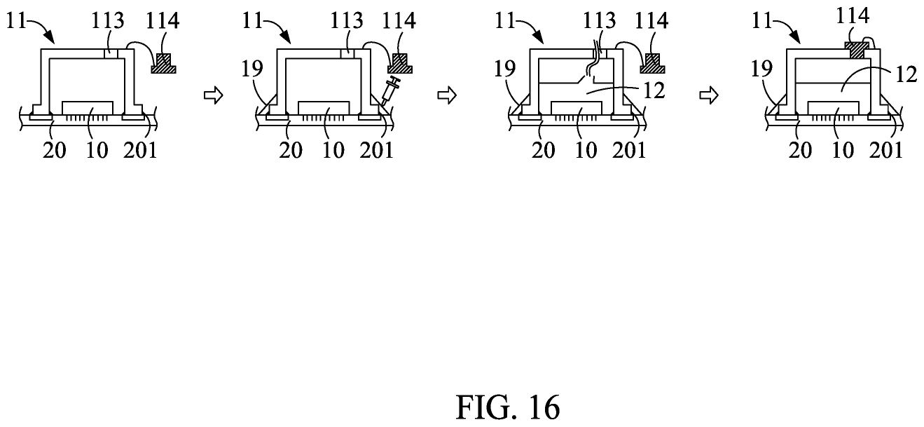

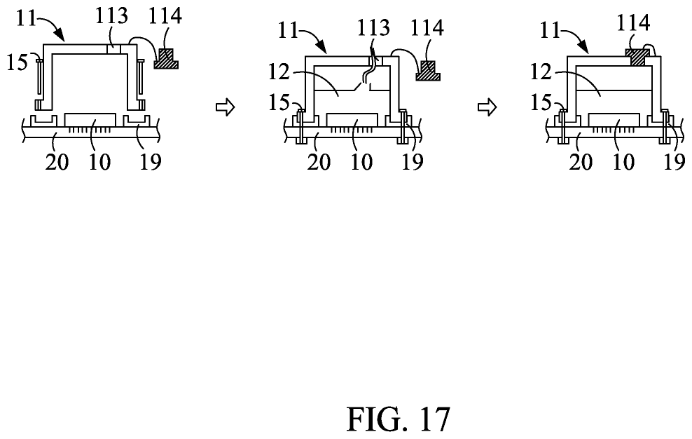

Referring to FIG. 13 to FIG. 17, in an embodiment of the present disclosure, a difference from the above embodiments is that, the liquid cooler 12 is added into the filler 113 of the body 11 after the body 11 is disposed, placed, assembled, or coupled with the object 20 or the heat generator 10, and sealing is performed by using the switch 114; or the liquid cooler 12 is added before the body 11 is disposed at the object 20 or the heat generator 10, thereby enabling the present disclosure to better meet actual assembly requirements.

In an embodiment of the present disclosure, the body 11 is first soldered or welded at the heat generator 10 (or the object 20) and fixed, sealed, or packaged by the fixing element 19, wherein the fixing element 19 is a viscous element, a jelly element, a welding element, a plastic body, solder, glue, a thermoplastic element, or a heat curable element, thereby enabling the present disclosure to better meet actual assembly requirements.

In an embodiment of the present disclosure, the body 11 is first soldered, welded, assembled, or coupled at the heat generator 10 (or the object 20) and fixed, sealed, or packaged by the fixing element 19, and the liquid cooler 12 is added into the body 11, thereby enabling the present disclosure to better meet actual assembly requirements.

In an embodiment of the present disclosure, the body 11 is first assembled at the object 20 by using the assembly element 15 and fixed, sealed, or packaged by the fixing element 19, and the liquid cooler 12 is added into the body 11, thereby enabling the present disclosure to better meet actual assembly requirements.

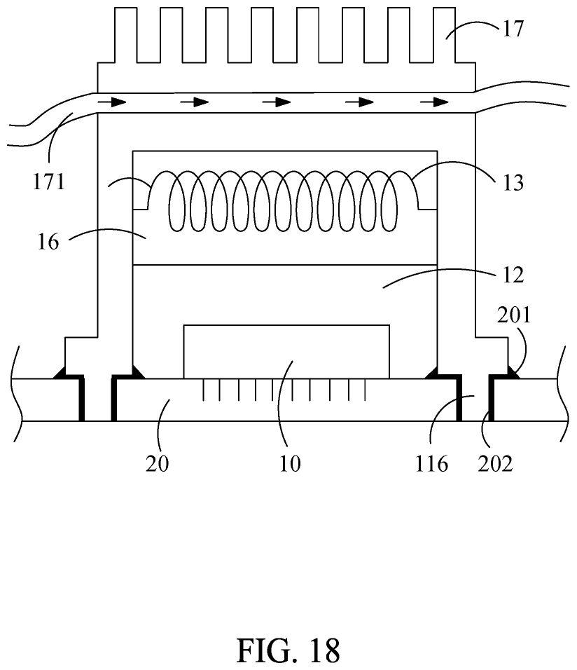

Referring to FIG. 18, in an embodiment of the present disclosure, the body 11 has a limiting portion 116 (or an anti-rotation portion), which is used to limit or prevent rotation of a corresponding structure 202 of the object 20, wherein the object 20 is a PCB, an iron plate, a metal body, or a plastic body, and the limiting portion 116 and the corresponding structure 202 may be welded or soldered and combined by using the welding portion 201 in between, or the limiting portion 116 and the corresponding structure 202 may be bonded and combined by using an adhesive in between, so as to weld, solder, or bond the body 11 at the object 20. Alternatively, a descending, sinking, or downward force or traction is produced by heat welding or soldering performed for cooling the solder from a liquid state to a solid state, or a descending, sinking, or downward force or traction is produced by bonding, such that the heat dissipation module 1 or the body adheres to, leans against, or becomes close to the heat generator 10 or the object 20, thereby enabling the present disclosure to better meet actual assembly requirements

In conclusion, the heat dissipation module and the assembly method thereof according to the embodiments of the present invention provide a stable configuration and an efficiently improved heat dissipation effect.

It should be noted that the embodiments of the present invention are described above for illustration purposes and are not to be construed as limitations to the scope of the claims of the present invention.

What is claimed is:

1. A heat dissipation module, comprising a body, which is provided with a liquid cooler or a gaseous cooler, and the heat dissipation module is disposed at a heat generator to perform heat dissipation.

2. The heat dissipation module according to claim 1, wherein the liquid cooler receives heat of the heat generator and becomes a gas, and is condensed to a liquid at the body.

3. The heat dissipation module according to claim 1, wherein the body is provided with a condenser that is used to condense a gas into a liquid, wherein the condenser is a condenser pipe, a metal body, a heat sink, a cooling fluid, a cooling gas, or a cooling fin, or the condenser is provided with a flow channel for a liquid fluid or a gaseous fluid to flow.

4. The heat dissipation module according to claim 1, wherein the body or the condenser of the body is provided with a fan used to dissipate heat, or the body is provided with one or more heat sinks and at least one of the heat sinks is provided with a flow channel used to guide flow of the liquid cooler.

5. The heat dissipation module according to claim 1, wherein the body is provided with a heat sink used to guide, absorb or dissipate heat between the heat generator and the liquid cooler or the gaseous cooler, the heat sink is connected to a gas-cooling device to perform heat dissipation, or the heat sink is connected to a liquid-cooling device to perform heat dissipation, or an intermediate heat sink or a heat sink medium is provided between the body and the heat generator, the intermediate heat sink or the heat sink medium used to guide or absorb heat between the body and the heat generator.

6. The heat dissipation module according to claim 1, wherein the body is provided therein with a non-liquid space used to accommodate a gas formed from a liquid; or the non-liquid space is located between the liquid cooler and the condenser, or the non-liquid space is located in the liquid cooler, or the non-liquid space is located in the condenser.

7. The heat dissipation module according to claim 1, wherein the body, the heat sink, or the condenser is provided with an information transmission assembly or a light emitter, the information transmission assembly or the light emitter used to transmit or display a temperature of the body, the heat dissipation module, the liquid cooler, or the gaseous cooler, or detect or display a temperature of the non-liquid space, or detect or display a temperature of the condenser, or detect or display a temperature of the heat sink, or detect or display heat dissipation information, temperature information or light emitting display of the heat generator, the liquid cooler or the condenser.

8. The heat dissipation module according to claim 1, wherein the body is provided with a filler used to fill the liquid condenser, wherein the filler comprises a switch.

9. The heat dissipation module according to claim 1, wherein further comprising a liquid displacement device, which moves the liquid cooler to the heat sink or the condenser to perform heat dissipation.

10. The heat dissipation module according to claim 1, wherein the body is provided with a heat sink which is connected to a gas-cooling device to perform heat dissipation, and the gas-cooling device imports compressed air such that one end of the gas-cooling device imports cold air into the heat sink, a heat conductor, a cooler or the body to perform heat dissipation, heat conduction or cooling, or the gas-cooling device is a vortex tube such that one end of the gas-cooling device imports air and one other end exports hot air.

11. The heat dissipation module according to claim 1, wherein the liquid cooler is added into the body after the body is disposed, placed, assembled, or coupled at the object or the heat generator, or the liquid cooler is added before the body is disposed at the object or the heat generator.

12. The heat dissipation module according to claim 1, wherein the body is first welded, assembled, or coupled at the heat generator or object and then fixed, sealed or packaged by a fixing element; or the body is first welded, soldered, assembled, or coupled at the heat generator or object, fixed and then sealed or packaged by the fixing element, and the liquid cooler is added into the body.

13. The heat dissipation module according to claim 1, wherein the body has a limiting portion or an anti-rotation portion used to limit or prevent rotation of a corresponding structure of the object.

14. The heat dissipation module according to claim 1, wherein the heat dissipation module or the body is welded, soldered, or bonded at the object or the heat generator, such that the heat dissipation module or the body is arranged at the heat generator or the body; a descending, sinking, or downward force or traction is produced by heat welding or soldering performed for cooling a solder from a liquid state to a solid state or a descending, sinking, or downward force or traction is produced by bonding, such that the heat dissipation module or the body adheres to, leans against, or becomes close to the heat generator or the object.

15. An assembly method of a heat dissipation module, the method for coupling the heat dissipation module according to claim 1, to dispose, assemble, couple, weld, solder, or bond the body or the heat dissipation module by a tool or an automated process at an object or a heat generator, such that the body or the heat dissipation module is disposed, assembled, coupled, welded, soldered, or bonded at the object or the heat generator.

16. The assembly method of a heat dissipation module according to claim 15, wherein the body or the heat dissipation module is picked up by a tool or an automated process, compared with a configuration position of the object or the heat generator by a comparison device to perform disposing, assembling, coupling, welding, soldering, or bonding; or the body or the heat dissipation module are picked up by the tool or the automated process to move the body or the heat dissipation module to a default height distanced from an assembly position of the object or the heat generator, and the body or the heat dissipation module is released or loosened, such that the body or the heat dissipation module is disposed, assembled, coupled, welded, soldered, or bonded at object or the heat generator; or the body or the heat dissipation module is picked up by the tool or the automated process to move the body or the heat dissipation module, the body or the heat dissipation module is elastically pressed downward by the tool, and the body or the heat dissipation module is released or loosened, such that the body or the heat dissipation module is disposed, coupled, welded, soldered, or bonded at the object or the heat generator; or the body or the heat dissipation module is picked up by the tool or the automated process to move the body or the heat dissipation module, it is sensed by the tool that the body or the heat dissipation module comes into contact with the object or the heat generator and the body or the heat dissipation module is released or loosened, such that the body or the heat dissipation module is disposed, assembled, coupled, welded, soldered, or bonded at the assembly position of the object or heat generator; or the body or the heat dissipation module is picked up by the tool or the automated process to move the body or the heat dissipation module to the object or the heat generator, the body or the heat dissipation module is pressed downward, and the body or the heat dissipation module is released or loosened, such that the body or the heat dissipation module is disposed, assembled, coupled, welded, soldered, or bonded at the object or the heat generator; or the body or the heat dissipation module is picked up by the tool or the automated process to move the body or the heat dissipation module to the object or the heat generator, and the body or the heat dissipation module is released or loosened, such that the body or the heat dissipation module is disposed, assembled, coupled, welded, soldered, or bonded at the object or the heat generator.
